(19) United States
(12) Patent Application Publication
(10) Pub. No.: US 2019/0043991 A1
(43) Pub. Date: Feb. 7, 2019

(54) INCREASED GATE COUPLING EFFECT IN MULTIGATE TRANSISTOR

(71) Applicant: GLOBALFOUNDRIES Singapore Pte. Ltd., Singapore (SG)

(72) Inventors: Shyue Seng TAN, Singapore (SG); Kiok Boone Elgin QUEK, Singapore (SG); Eng Huat TOH, Singapore (SG)

(21) Appl. No.: 15/665,441

(22) Filed: Aug. 1, 2017

(51) Int. Cl. H01L 29/788; H01L 29/78; H01L 29/423; H01L 29/51; H01L 29/08; H01L 29/66

(52) U.S. Cl. CPC H01L 29/7881; H01L 29/78391; H01L 29/42364; H01L 29/45; H01L 29/0847; H01L 29/6684; H01L 29/66825; H01L 29/516

(57) ABSTRACT

A non-volatile memory (NVM) device and a method for forming the NVM device are presented. The NVM device includes a substrate having a device region, a gate stack having a floating gate (FG) and a control gate (CG) over the device region, and source/drain (S/D) regions adjacent to the sidewalls of the gate. The FG includes a FG dielectric and a FG electrode. The CG includes a composite CG dielectric and a CG electrode. The composite CG dielectric includes a first CG dielectric and a ferroelectric second CG dielectric. The ferroelectric second CG dielectric is configured to have a negative capacitance to increase gate coupling ratio of the NVM device.

### BACKGROUND

Non-volatile memory (NVM) devices have achieved widespread adoptions for code and data storage applications. An advantage of NVM devices is that they are able to retain stored data even when the power supply is interrupted. NVM devices include flash devices which can be programmed using electrical signals. A NVM memory cell, for example, includes a control gate (CG) and a floating gate (FG) coupled in series. The FG stores data programmed into the memory cell, while the CG selects the memory cell to be programmed or erased. Charges are stored or discharged from the FG, representing the first and second states of the memory cell.

An important aspect for NVM cell performance is to have a high gate coupling ratio between the FG and CG. However, conventional NVM devices can only achieve a gate coupling ratio of about 0.7-0.8. Such low gate coupling ratio limits the scalability of conventional NVM devices. In addition, low gate coupling ratio results in increased power consumption as well as reduced device performance. For example, low gate coupling ratio between the FG and CG results in a longer program or erase time for NVM devices. It is hence desirable to provide NVM cells with enhanced gate coupling ratio.

The present disclosure is directed to a NVM cell with high gate coupling ratio to improve scalability and performance as well as to reduce power consumption.

### SUMMARY

Embodiments generally relate to semiconductor devices or integrated circuits (ICs) and methods for forming the devices. In one embodiment, a device is disclosed. The device includes a substrate having a device region, a gate stack having a floating gate (FG) and a control gate (CG) over the device region, and source/drain (S/D) regions adjacent to the sidewalls of the gate. The FG includes a FG dielectric and a FG electrode. The CG includes a composite CG dielectric and a CG electrode. The composite CG dielectric includes a first CG dielectric and a ferroelectric second CG dielectric. The ferroelectric second CG dielectric is configured to have a negative capacitance to increase gate coupling ratio of the device.

In another embodiment, a method of forming a device is described. The method includes providing a substrate having a device region, forming a gate stack having a floating gate (FG) and a control gate (CG) over the device region, and forming source/drain (S/D) regions adjacent to the sidewalls of the gate. The FG includes a FG dielectric and a FG electrode. The CG includes a composite CG dielectric and a CG electrode. The composite CG dielectric includes a first CG dielectric and a ferroelectric second CG dielectric. The ferroelectric second CG dielectric is configured to have a negative capacitance to increase gate coupling ratio of the device.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIGS. 1a-b show schematic diagrams of an embodiment of a non-volatile memory cell and corresponding parasitic capacitance model;

FIGS. 2a-b show top and cross-sectional views of an embodiment of a non-volatile memory cell; and

FIGS. 3a-g show cross-sectional views of a process for forming a device.

### DETAILED DESCRIPTION

Embodiments generally relate to devices, for example, semiconductor devices or integrated circuits (ICs). More particularly, embodiments relate to ICs with NVM memory devices with a high gate coupling ratio. The ICs can be any type of ICs, such as stand-alone NVM devices or ICs embedded with NVM devices. Other types of devices may also be useful. The devices or ICs can be incorporated into or used with, for example, consumer electronic products, or other types of products.

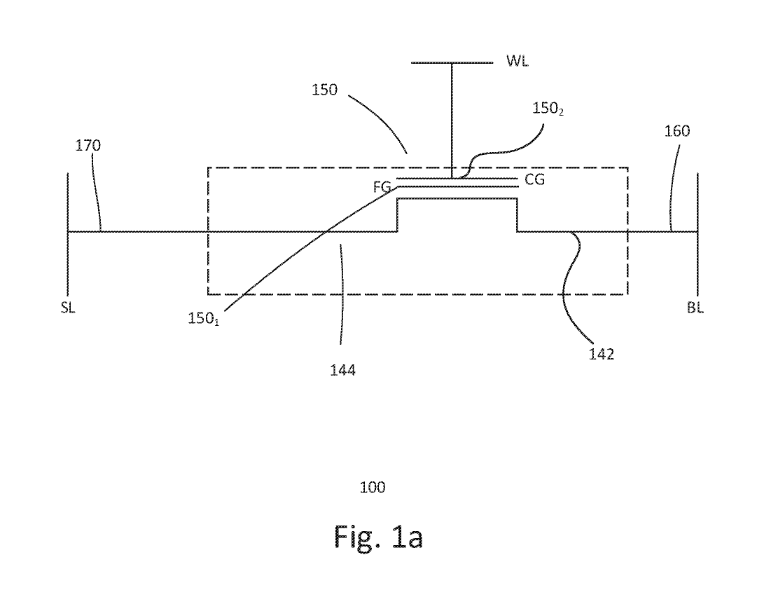

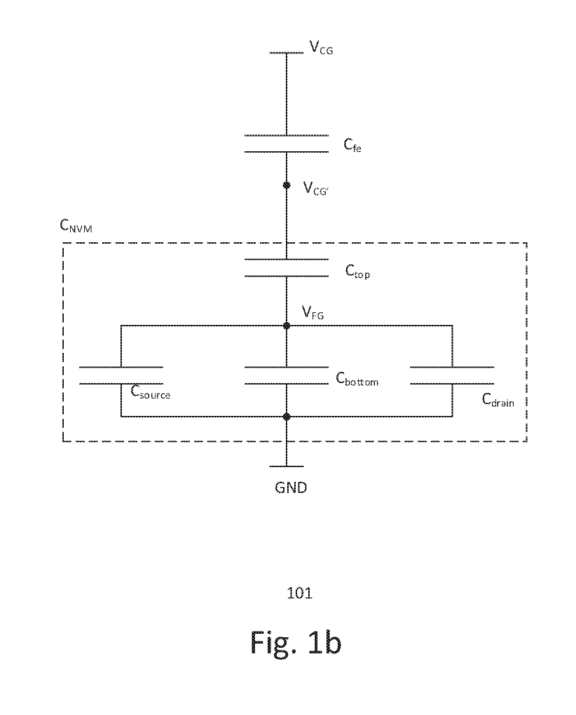

FIG. 1a shows a simplified schematic diagram of an embodiment of a device 100 and FIG. 1b shows a corresponding parasitic capacitance model 101 of the device. The device is a non-volatile memory (NVM) cell. The memory cell may be a multi-gate metal oxide semiconductor field effect transistor (MOSFET). In one embodiment, the memory cell includes high gate coupling ratio. Other suitable types of memory cells may also be useful.

As shown, the memory cell includes a gate 150. The gate is a gate stack having first and second gates 150₁ and 150₂ disposed between first and second cell terminals 160 and 170. The first gate serves as a floating gate (FG) and the second gate serves as a control gate (CG). The FG is disposed on the substrate below the CG. A gate stack is disposed between first and second source/drain (S/D) regions 142 and 144. The first S/D region may serve as the first cell terminal and the second S/D region may serve as the second cell terminal.

The FG includes a FG electrode and a FG dielectric. The FG electrode may be a polysilicon FG electrode. As for the FG dielectric, it may be a thermal silicon oxide FG dielectric. The FG stores or discharge charges, representing first and second states of the NVM cell. The CG includes a CG electrode and a CG dielectric. The CG electrode may be a polysilicon CG electrode. In one embodiment, the CG dielectric is a composite CG dielectric having first and second CG gate dielectrics. The first CG dielectric is below the second CG dielectric. For example, the first CG dielectric is an oxide-nitride-oxide combo (ONO) or a thermal silicon oxide gate dielectric and the second CG dielectric is a ferroelectric gate dielectric. The ferroelectric gate dielectric may be barium-titanium oxide (BaTiO₃). Other types of ferroelectric dielectrics, such as hafnium-zirconium oxide (HfZrO₂) or doped hafnium oxide (HfO₂) may also be used as the ferroelectric gate dielectric. Doped hafnium oxide may include tetragonal HfO₂, such as Si:HfO₂ or Al:HfO₂.

The first cell terminal is coupled to a bitline BL and the second cell terminal is coupled to a source line SL. The first gate 150₁ is a FG gate which serves as a storage gate. As for the second gate 150₂, it serves as a control gate terminal which is coupled to a word line WL.

As described, the CG dielectric includes a second CG ferroelectric dielectric. The second CG ferroelectric dielectric is configured to provide negative capacitance. This enables a gate coupling ratio of 1 or greater.

The parasitic capacitance model of the NVM cell is shown in FIG. 1b. The parasitic capacitance model includes a plurality of parasitic capacitances produced by various components of the NVM cell disposed between V_{CG} and GND. In one embodiment, a parasitic ferroelectric capacitance C_{fe} is produced by the ferroelectric CG dielectric layer and is coupled in series to a parasitic capacitance Cₜₒₚ produced by the oxide CG dielectric layer. Between Cₜₒₚ and C_{fe} is V_{CG′}. The parasitic capacitances C_{source} produced by the second S/D region 144, C_{drain} produced by the first S/D region 142, and C_{bottom} produced by the FG dielectric are parallel capacitances coupled between V_{FG} and GND. The parasitic capacitances Cₜₒₚ, C_{source}, C_{drain} and C_{bottom} together form parasitic capacitance C_{NVM}.

Based on the divider rule, the value V_{C}& is defined by Equation 1 below:

$${V}_{CG}^{′} = {V}_{CG} * \frac{{C}_{fe}}{{C}_{fe} + {C}_{NVM} } ; \qquad ( Equation 1 )$$

and where

$$\frac{{C}_{fe}}{{C}_{fe} + {C}_{NVM} }$$

equals to the gate coupling ratio, and

C_{NVM} is the reciprocal of

$$\frac{1}{{C}_{top}} + \frac{1}{( {C}_{source} + {C}_{bot} + {C}_{drain} )} .$$

As discussed, C_{fe} is configured to produce negative capacitance for devices with the second CG ferroelectric dielectric. Since C_{fe} is negative, the value V_{CG′} is defined by Equation 2 below:

$${V}_{CG}^{′} = {V}_{CG} * \frac{\vert {C}_{fe} \vert}{\vert {C}_{fe} \vert - {C}_{NVM}} . \qquad ( Equation 2 )$$

In one embodiment, ═C_{fe}| is selected to produce a total positive capacitance. For example, |C_{fe}| is greater than C_{NVM} to produce a positive total capacitance. In one embodiment, |C_{fe}| is greater than C_{NVM} by 4×. This results in a stable positive total capacitance without hysteresis.

As an example, assume that C_{NVM}=0.8. Using the 4× rule, |C_{fe}| is 3.2. Based on Equation 2, if V_{CG} is 10V, then V_{CG′} will be 13.3 V. Since C_{NVM} is equal to 0.8 and V_{CG′} is 13.3 V, V_{FG} is 10.67 V (0.8*13.3V). As such, this results in a CG to FG coupling ratio of 106.7%.

In one embodiment, the second CG dielectric thickness t_{fe} is selected to produce total positive capacitance. To produce a total positive capacitance, the second CG dielectric thickness is less than a critical thickness t_{fe, critical}. The critical thickness can be defined by Equation 3 below:

$$\frac{1}{2 * \vert \partial \vert * {C}_{NVM}} = {t}_{fe , critical} ; \qquad ( Equation 3 )$$

where
t_{fe,critical} is the critical thickness of the second CG dielectric layer; and ∂ is the fitting parameter for steady-state polarization of the second CG dielectric layer.
   In one embodiment, t_{fe} is less than t_{fe,critical}. Assume that the ferroelectric material is BaTiO₃ which has ∂=1e−7 mF and the C_{NVM}=1.56 fF/um², then t_{fe,critical} may be about 5 nm. For example, t_{fe} should be less than 5 nm to produce a stable positive capacitance without hysteresis.

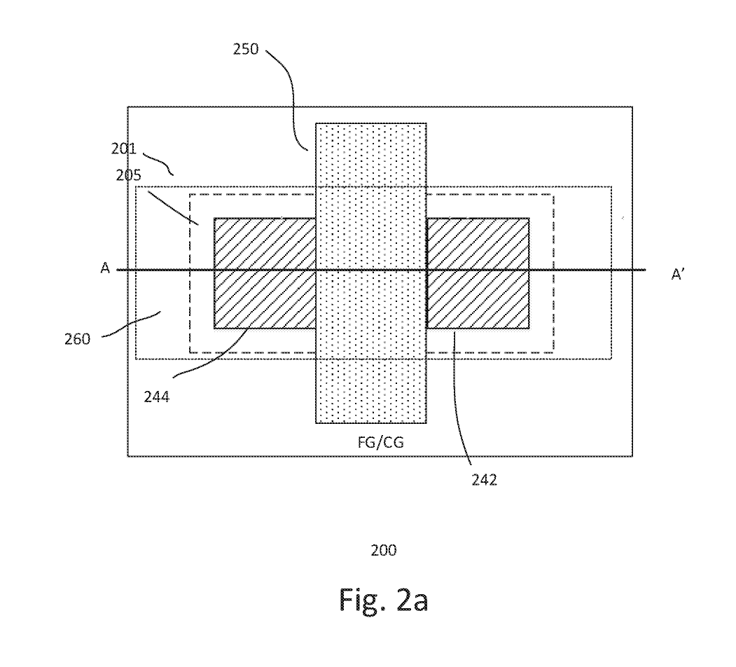

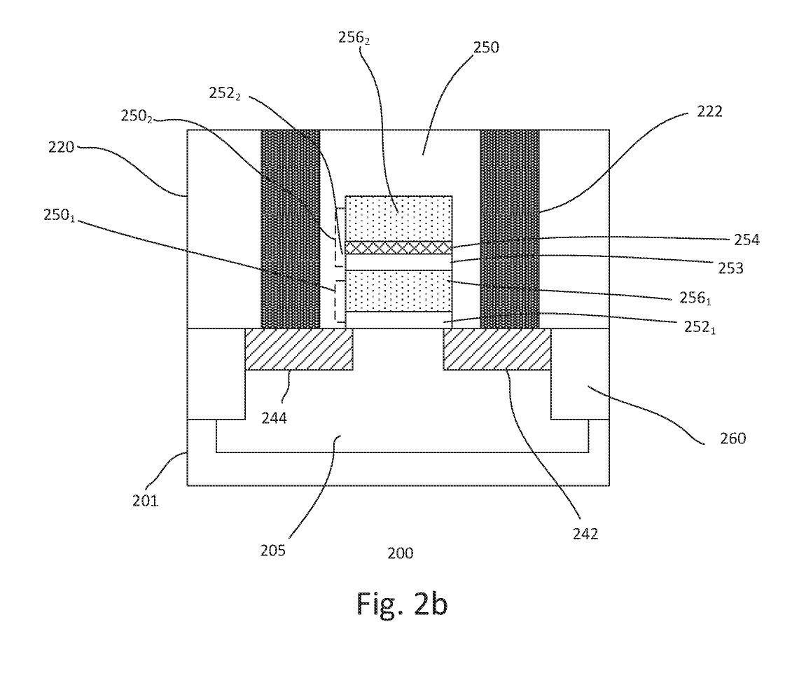

FIGS. 2a-b show simplified top and cross-sectional views of an embodiment of a device 200. The cross-sectional view is along A-A′. The device, for example, is an integrated circuit (IC). As shown, the device includes a multi-gate NVM cell. The NVM cell is similar to the NVM cells described in FIGS. 1a-b. Common elements may not be described or described in detail.

The NVM cell is disposed in the cell region of a substrate 201. The substrate, for example, may be a semiconductor substrate, such as a silicon substrate. Other types of substrates or wafers may also be useful. For example, the substrate may be a silicon germanium, germanium, a gallium arsenide, or a crystal-on-insulator (COI) such as silicon-on-insulator (SOI) substrate. The substrate maybe a doped substrate. For example, the substrate can be lightly doped with p-type dopants. Providing a substrate with other types of dopants or dopant concentrations as well as an undoped substrate, may also be useful.

The cell region, for example, is part of an array region having a plurality of memory cells. The substrate may include other types of device regions. The substrate, for example, may include low voltage (LV) device region for LV metal oxide semiconductor (MOS) transistors, medium voltage (MV) device regions for MV MOS transistors, and high voltage (HV) device regions for HV MOS transistors. Other device regions may also be provided on the substrate.

The device may include doped regions having different dopant concentrations. For example, the device may include heavily doped (x⁺), intermediately doped (x) and lightly doped (x⁻) regions, where x is the polarity type which can be p or n. A lightly doped region may have a dopant concentration of about 10¹⁶ to 10¹⁷ cm⁻³, an intermediately doped region may have a dopant concentration of about 10¹⁸ to 10¹⁹ cm⁻³, and a heavily doped region may have a dopant concentration of about 10²⁰ to 10²¹ cm⁻³. The doping concentrations, for example, are for 55 nm technology node. Providing other dopant concentrations for the different doped regions may also be useful. For example, dopant concentrations may vary depending on, for example, the technology node. P-type dopants may include boron (B), aluminum (Al), indium (In) or a combination thereof, while n-type dopants may include phosphorous (P), arsenic (As), antimony (Sb) or a combination thereof.

An isolation region 260 is provided. The isolation region surrounds the cell region. For example, the isolation region surrounds the cell region. The isolation region isolates the cell region from other device regions. Other isolation regions may also be provided to isolate other device regions. The isolation region may be a shallow trench isolation (STI) region. A STI region includes an isolation trench filled with isolation or dielectric materials. Other types of isolation regions may also be employed. For example, the isolation region may be a deep trench isolation (DTI) or a field oxide (FOX) isolation region. The STI regions, for example, extend to a depth of about 2000-5000 Å. Providing isolation regions which extend to other depths may also be useful.

A cell well 205 is disposed in the substrate in the cell region. In one embodiment, the cell well is disposed within the device isolation region of cell region, for example, a device wall. In one embodiment, the depth or bottom of the device well is below the isolation region surrounding the cell region. Providing a cell well having other depths may also be useful. Other configuration of cell wells may also be useful.

The cell well includes second polarity dopants for a first polarity type NVM cell. For example, a device well includes p-type dopants for a n-type NVM cell or n-type dopants for a p-type NVM cell. The cell well may be lightly (x⁻) or intermediately (x) doped with second polarity type dopants. Other dopant concentration may also be useful for the cell well.

A deep isolation well (not shown) may be provided for the cell region. The deep isolation well, for example, is first polarity type doped well. The deep isolation well isolates the cell well from the substrate. The substrate may include other device wells for other types of devices. For example, other device wells may be provided for other device regions of the substrate.

The NVM cell includes a gate 250 disposed on a substrate between first and second S/D regions 242 and 244. The gate is a gate stack which includes first and second gates 250₁ and 250₂ disposed on the substrate in the device region. The first gate serves as a floating gate (FG) and the second gate serves as a control gate (CG). The second gate is disposed above the first gate.

The FG 250₁ stores or discharge charges, representing first and second states of the NVM cell. The FG includes a FG gate electrode 256₁ disposed over a FG gate dielectric 252₁. The FG gate dielectric 252₁ is disposed on the substrate. The FG electrode 256₁ may be a polysilicon FG electrode. As for the FG dielectric, it may be a thermal silicon oxide FG dielectric. The thickness of the FG gate electrode may be about 1000 Å and the thickness of the FG dielectric may be about 80 Å. Other thicknesses for the FG electrode and FG dielectric may also be useful.

As for the CG 250₂, it includes a CG electrode 256₂ disposed over a CG dielectric 252₂. The CG gate electrode may be a polysilicon CG electrode. In one embodiment, the CG dielectric includes a composite gate dielectric which includes a second CG gate dielectric 254 disposed on the first gate CG dielectric 253. The first CG dielectric 253 is disposed on the FG electrode 256₁ while the CG electrode 256₂ is disposed on the second CG dielectric 254. For example, the first CG dielectric is an oxide-nitride-oxide combo (ONO) or a thermal silicon oxide gate dielectric and the second CG dielectric is a ferroelectric gate dielectric. The ferroelectric gate dielectric may be barium-titanium oxide (BaTiO₃). Other types of ferroelectric dielectrics, such as hafnium-zirconium oxide (HfZrO₂) or doped hafnium oxide (HfO₂) may also be used as the ferroelectric gate dielectric. Doped hafnium oxide may include tetragonal HfO₂, such as Si:HfO₂ or Al:HfO₂. The thickness of the first CG dielectric, for example, an ONO dielectric, may be about 180 Å. The thickness of the second CG dielectric may be calculated based on Equation 1 to 3. For example, as discussed, the thickness of a BaTiO₃ ferroelectric dielectric may have a thickness of less than 5 nm. Other thicknesses may also be useful.

As for the S/D regions 242 and 244, they are heavily doped regions with first polarity type dopants. The S/D region may extend from the surface of the substrate to a depth of about 60 nm. Other depths for the S/D regions may also be useful. The S/D regions, as shown, extend slightly under the gate.

In some embodiments, the S/D region may include a lightly doped (LD) extension region. For example, each of the first and second S/D regions includes a LD extension region. The LD extension regions are lightly doped regions. Typically, the LD extension regions have a depth shallower than the S/D regions. Other configurations of LD extension and S/D regions may also be useful.

The gate stack may include dielectric sidewall spacers, such as a silicon nitride spacer. The sides of the gate electrodes may include an oxide liner. In the case of LD extension regions, they extend under the gate while the heavily doped S/D regions are aligned with the spacers. For example, the spacers facilitate in forming the S/D regions.

The S/D regions serve as cell terminals of the NVM cell. For example, the first S/D region 242 serves as the first cell terminal and the second S/D region 244 serves as the second cell terminal. The S/D regions and CG gate electrode may include metal silicide contacts, such as nickel-based silicide contacts. Other types of metal silicide contacts may also be useful.

A contact dielectric layer 220 is disposed over the substrate, covering the substrate and gate stack. The contact dielectric layer may be a silicon oxide layer formed by chemical vapor deposition (CVD). Other types of dielectric layers may also be useful. The contact dielectric layer, for example, serves as the first contact level of a back-end-of-line (BEOL) dielectric layer having a plurality of inter-level dielectric (ILD) levels. An ILD level includes a contact or via dielectric layer below a metal level dielectric layer. Contacts are disposed in the contact dielectric layer and metal lines are disposed in the metal level dielectric layer. As shown, contacts 222 are disposed in the contact dielectric layer. The contacts are coupled to the cell terminals. In addition, a contact may be provided which is coupled to the CG.

The contact to the first cell terminal is coupled to a bitline BL in a metal level above, the contact to the second cell terminal is coupled to a source line SL in a metal level above and the contact coupled to the CG is coupled to a wordline WL in a metal level above. Lines which are perpendicular, such as WL and BL, are provided on different metal levels.

As discussed, the CG includes a ferroelectric second CG dielectric which produces negatively capacitance to increase gate coupling ratio. In one embodiment, the thickness of the second CG dielectric is selected to produce a gate coupling ratio of ≥1. Preferably, the gate coupling ratio is and over 107%. In one embodiment, the thickness of the ferroelectric GC dielectric is less than a critical thickness t_{fe,critical} to produce a total positive capacitance. In one embodiment, |C_{fe}|>C_{NVM} by 4× to ensure no hysteresis and to produce a stable positive total capacitance. In one embodiment, the critical thickness is about 5 nm. Other critical thickness may also be useful, depending on the ferroelectric material used and C_{NVM}.

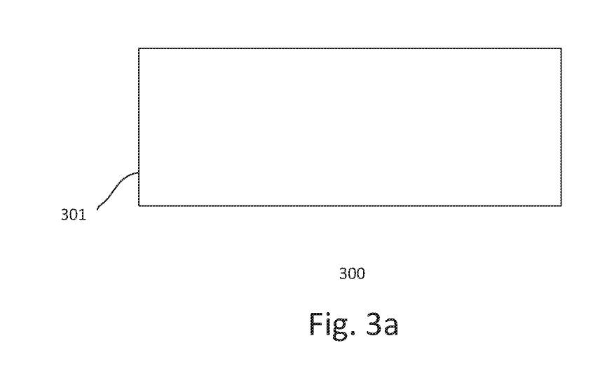

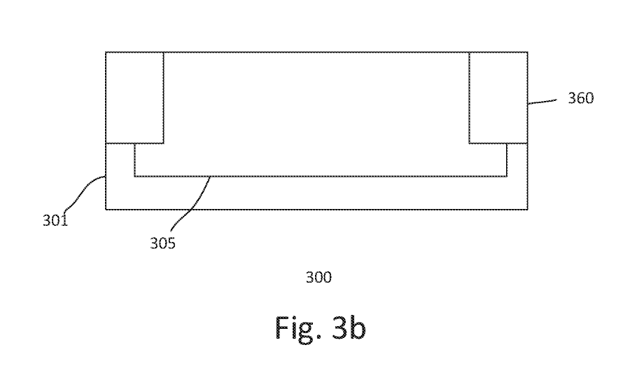

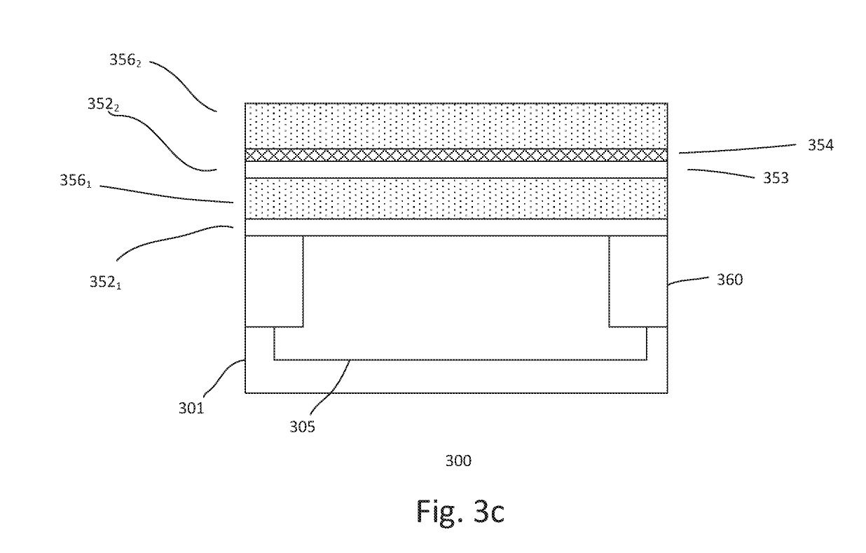

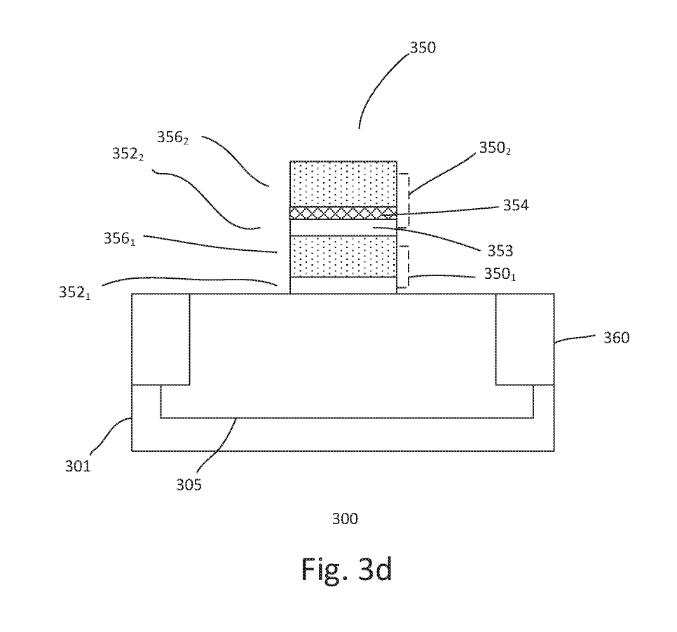

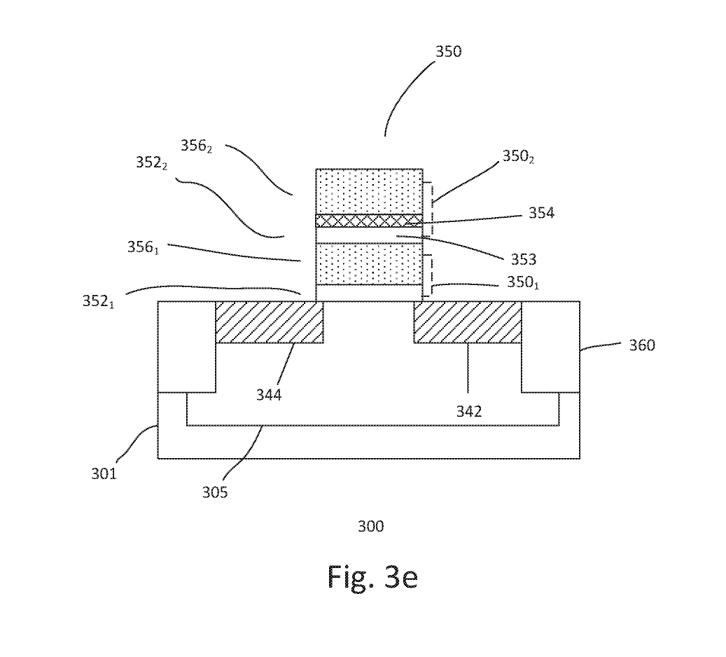

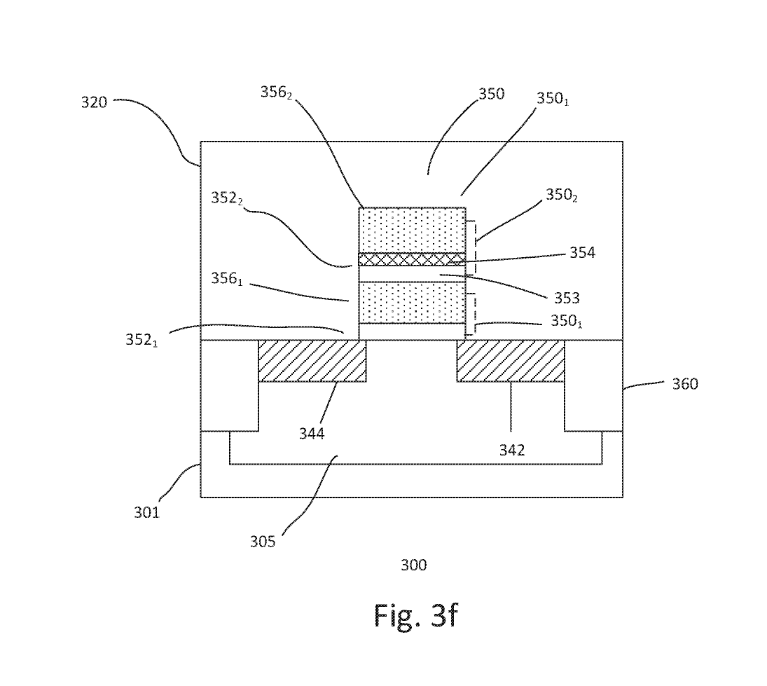

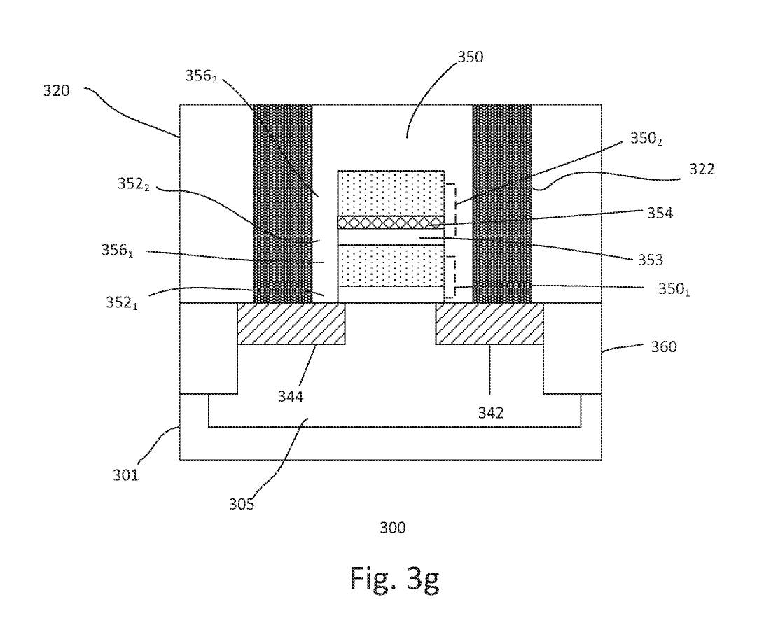

FIGS. 3a-g show cross-sectional views of an embodiment of a process for forming a device 300. The device, for example, is similar to that described in FIGS. 1a-b and FIGS. 2a-b. Common elements may not be described or described in detail. Referring to FIG. 3a, a substrate 301 is provided. The substrate, in one embodiment, is a silicon substrate. The substrate, for example, may be a semiconductor substrate, such as a silicon substrate. Other types of substrates or wafers may also be useful. For example, the substrate may be a silicon germanium, germanium, a gallium arsenide, or a crystal-on-insulator (COI) such as silicon-on-insulator (SOI) substrate. The substrate maybe a doped substrate. For example, the substrate can be lightly doped with p-type dopants. Providing a substrate with other types of dopants or dopant concentrations as well as an undoped substrate, may also be useful.

The substrate, as shown in FIG. 3b, is prepared with a cell region in which a NVM cell is formed. Preparing the cell region may optionally include forming a deep isolation well. The deep isolation well, for example, may serve to isolate the cell region from the substrate. The isolation well includes an opposite polarity type dopant than the doped substrate. For example, in the case of a lightly doped p-type substrate, the deep isolation well may be n-type. For example, the n-type deep isolation well is implemented by an implant mask. The dopant concentration of deep isolation well may be about 10¹⁶ to 10¹⁷ cm⁻³. Other dopant concentrations for the deep isolation well may also be useful. The depth of the deep isolation well is sufficient to isolate the device region from the substrate. The depth, for example, may be about 2.5 um. Other depths for the deep isolation well may also be useful. Forming the deep isolation well may be achieved by implanting isolation well dopants. In some cases, multiple implants may be employed to form the deep isolation well.

An isolation region 360 may be formed in the substrate. The isolation regions, for example, are STI region. Other types of isolation regions may also be formed. A STI region surrounds a device region. For example, a cell isolation region surrounds the cell region. In one embodiment, the isolation region also defines an assist gate (AG) region. Various processes can be employed to form the STI regions. For example, the substrate can be etched using etch and mask techniques to form isolation trenches which are then filled with dielectric materials such as silicon oxide by chemical vapor deposition (CVD). Chemical mechanical polishing (CMP) can be performed to remove excess oxide and provide a planar substrate top surface. Other processes or materials can also be used to form the STIs. The depth of the STIs, for example, is about 3000-5000 Å. Other depths for the STIs may also be useful.

A cell well 305 is formed in the cell region. In one embodiment, the cell well includes second polarity type dopants for a first polarity type NVM cell. The cell well may be a lightly or intermediately doped first polarity type doped cell well. The cell well may have a depth which is deeper than the bottom of the isolation region but shallower than the deep isolation well.

The cell well may be formed by implanting second polarity type dopants. An implant mask may be used to implant the second polarity type dopants. For example, the implant mask exposed the cell region in which dopants are to be implanted. An anneal is performed after forming the device wells. The anneal activates the dopants.

As described, the process is used for preparing the cell region. Preparing other device regions, such as LV, MV and HV device regions may also be useful. Isolation regions may be formed to isolate different regions. Implants may be performed to form the device wells. Separate implant processes may be employed to form differently doped or different types of device wells.

Referring to FIG. 3c, gate layers of the gate stack are formed on the substrate. For example, a FG dielectric 352₁, a FG electrode 356₁, a CG dielectric 352₂ which includes a first CG dielectric 353 and a second CG dielectric 354, and CG electrode 3562 are formed on the substrate. The FG dielectric may be silicon oxide formed by thermal oxidation, the FG gate electrode may be a polysilicon formed by CVD, the first CG dielectric may be ONO formed by thermal oxidation, the second CG dielectric may be a ferroelectric layer formed by sputtering or CVD and the CG electrode may be polysilicon formed by CVD. Other processes may also be used to form the various gate layers.

In FIG. 3d, the gate layers are patterned to form a gate stack with a FG 350₁ and a CG 3502. To form the gate stack, mask and etch techniques may be used. For example, a soft mask, such as a photoresist mask, may be formed over the CG gate electrode layer. An exposure source may selectively expose the photoresist layer through a reticle containing the desired pattern. After selectively exposing the photoresist layer, it is developed to form openings corresponding to the location where the gate layers are to be removed. To improve lithographic resolution, an anti-reflective coating (ARC) may be used below the photoresist layer.

The patterned mask layer serves as an etch mask for a subsequent etch process. For example, the etch transfers the pattern of the mask to the gate layers. The etch removes the gate layers unprotected by the mask, exposing the substrate. The etch, for example, may be an anisotropic etch, such as reactive ion etch (RIE). Other types of etch processes may also be useful. In one embodiment, an RIE is employed to pattern the gate layers to form the gate stack. After pattern the gate layers, the etch mask is removed, for example, by ashing. Other techniques for removing the etch mask may also be useful.

As shown in FIG. 3e, a S/D implant is performed using an S/D implant mask to form first S/D regions 342 and 344 adjacent to the opposing sides of the gate stack. The implant implants first polarity type dopants to form heavily doped S/D regions. As shown, the S/D regions extend slightly under the gate.

In other embodiments, LDD extension regions and S/D regions are formed adjacent to the opposing sides of the gate. In such cases, a thermal oxidation process is performed to form oxide liners on the top and sidewalls of the gate electrodes of the gates. The thermal oxidation process also forms an oxide liner on the top of the gate electrode as well as the exposed surface of the substrate. The oxide liner lining the exposed substrate may serve as an implant screen oxide and an adhesion layer for the nitride spacer layer.

An extension implant using a LDD extension implant mask is performed to form LD extension regions (not shown) in the substrate adjacent to the gates. The extension regions extend underneath the gate. For example, an angled implant, such as a quad angled implant, may be employ to form the LD extension regions. The extension regions are lightly doped with first polarity type dopants.

A dielectric spacer layer (not shown) is formed on the substrate. In one embodiment, the spacer layer includes a nitride layer lining the substrate and gates. The spacer layer may be formed by CVD. The thickness of the spacer layer may be equal to a thickness of the spacers. For example, the thickness may be about 20 nm. Other thicknesses may also be useful. An anisotropic etch is performed, removing horizontal potions of the spacer layer to leave sidewall spacers on sidewalls of the gate. Thereafter, the S/D implant is performed to form the heavily doped first and second S/D regions.

Referring to FIG. 3f, metal silicide contacts may be formed on terminals or contact regions. For example, metal silicide contacts may be provided on the exposed top surface of the gate electrodes and the exposed S/D regions. Metal silicide contacts may also be formed in other contact regions for other devices as well as well contacts. The silicide contacts, for example, may be nickel-based silicide contacts. Other types of metal silicide contacts may also be useful. For example, the metal silicide contact may be cobalt silicide (CoSi). The silicide contacts may be about 50-300 Å thick. Other thickness of silicide contacts may also be useful. The silicide contacts may be employed to reduce contact resistance and facilitate contact to the back-end-of-line (BEOL) metal interconnects.

To form the silicide contacts, a metal layer is deposited on the surface of the substrate. The metal layer, for example, may be cobalt or an alloy thereof. Other types of metallic layers, such as nickel, or alloys thereof, may also be used. The metal layer can be formed by physical vapor deposition (PVD). Other types of metal elements that can be formed by other types of processes can also be useful.

An anneal may be performed. The anneal diffuses the metal dopants into the active substrate, forming a silicide layer. Excess metal not used in the silicidation of the active surface is removed by, for example, a wet removal process. For example, unreacted metal material is selectively removed to form the silicide contacts.

A first dielectric layer 320 is formed on the substrate. The dielectric layer covers the substrate and gate. The dielectric layer may be a silicon oxide dielectric layer formed by CVD. A planarizing process, such as CMP, is performed to form a planar top surface over the gate stack. The first dielectric layer serves as a first contact dielectric layer of the BEOL dielectric.

In FIG. 3g, contacts 322 are formed to contact regions on the substrate as well as the CG. The well contacts, for example, are used to biased wells. The optional well contacts may be biased or grounded. The contacts may be formed by etching via openings in the first contact dielectric layer, filling it with a conductive material, such as tungsten. Other types of conductive materials may also be useful. Excess conductive material may be removed by, for example CMP.

Thereafter, additional back-end-of-line (BEOL) processing is performed to complete forming the device. Such processes may include, for example, additional ILD levels, final passivation, dicing, packaging and testing. Other or additional processes may also be included.

The present disclosure may be embodied in other specific forms without departing from the spirit or essential characteristics thereof. The foregoing embodiments, therefore, are to be considered in all respects illustrative rather than limiting the invention described herein. Scope of the disclosure is thus indicated by the appended claims, rather than by the foregoing description, and all changes that come within the meaning and range of equivalency of the claims are intended to be embraced therein.

1. A device comprising:
a substrate defined with a device region;
a gate stack comprising
a floating gate (FG), the FG includes
a FG dielectric disposed over the substrate, and
a FG electrode disposed over the FG dielectric, and
a control gate (CG), the CG includes
a composite CG dielectric comprising
a first CG dielectric disposed over the FG electrode, the first CG dielectric comprising a silicon oxide gate dielectric, and
a second CG dielectric disposed over the first CG dielectric, the second CG dielectric comprises a ferroelectric second CG dielectric, and
a CG electrode disposed over the ferroelectric second CG dielectric;
a first source/drain (S/D) region disposed adjacent to the first sidewall of the gate stack;
a second S/D region disposed adjacent to the second gate sidewall of the second gate; and
wherein the ferroelectric second CG dielectric is configured to have a negative capacitance to increase gate coupling ratio.

2. The device of claim 1 wherein the first CG dielectric comprises an oxide-nitride-oxide combo (ONO) dielectric.

3. The device of claim 1 wherein
the first CG dielectric produces a parasitic capacitance Cₜₒₚ;
the ferroelectric second CG dielectric produces a parasitic ferroelectric capacitance C_{fe};
the FG dielectric produces a parasitic capacitance C_{bottom};
the first S/D produces a parasitic capacitance C_{drain}; and
the second S/D produces a parasitic capacitance C_{source}.

4. The device of claim 3 wherein the Cₜₒₚ, the C_{source}, the C_{drain} and the C_{bottom} together form a parasitic capacitance C_{NVM}.

5. The device of claim 4 wherein an absolute value of the C_{fe} of the ferroelectric second CG dielectric is larger than C_{NVM}.

6. The device of claim 4 wherein the ferroelectric second CG dielectric has a thickness less than a critical thickness of the ferroelectric second CG dielectric, wherein the critical thickness of the ferroelectric second CG dielectric is calculated by
$$\frac{1}{2 * \vert \partial \vert * {C}_{NVM}} = {t}_{fe , critical} .$$

7. The device of claim 1 wherein the ferroelectric second CG dielectric comprises barium-titanium oxide (BaTiO₃), hafnium-zirconium oxide (HfZrO₂) or doped hafnium oxide (HfO₂).

8. A device comprising:
a substrate defined with a device region;
a gate stack comprising
a floating gate (FG), the FG includes
a FG dielectric disposed over the substrate, and
a FG electrode disposed over the FG dielectric, and
a control gate (CG), the CG includes
a composite CG dielectric comprising
a first CG dielectric disposed over the FG electrode, and
a second CG dielectric disposed over the first CG dielectric, the second CG dielectric is configured to be a negative capacitance second CG dielectric, and
a CG electrode disposed over the second CG dielectric; and
wherein the negative capacitance second CG dielectric is configured to produce an overall positive parasitic capacitance C_{NVM} for the gate stack.

9. The device of claim 8 wherein the second CG dielectric comprises a ferroelectric second CG dielectric.

10. The device of claim 9 wherein the ferroelectric second CG dielectric comprises barium-titanium oxide (BaTiO₃), hafnium-zirconium oxide (HfZrO₂) or doped hafnium oxide (HfO₂).

11. The device of claim 8 wherein the first CG dielectric comprises an oxide-nitride-oxide combo (ONO) dielectric.

12. The device of claim 8 wherein
the first CG dielectric layer produces a parasitic capacitance Cₜₒₚ;
the second CG dielectric layer produces a parasitic capacitance C_{fe};
the FG dielectric produces a parasitic capacitance C_{bottom};
a first S/D in the substrate adjacent to a fist sidewall of the gate stack produces a parasitic capacitance C_{drain}; and
a second S/D in the substrate adjacent to the fist sidewall of the gate stack produces a parasitic capacitance C_{source}.

13. The device of claim 12 wherein the Cₜₒₚ, the C_{source}, the C_{drain} and the C_{bottom} together form the parasitic capacitance C_{NVM}.

14. The device of claim 13 wherein an absolute value of the C_{fe} of the second CG dielectric is larger than C_{NVM}.

15. The device of claim 13 wherein the second CG dielectric has a thickness less than a critical thickness of the second CG dielectric, wherein the critical thickness of the second CG dielectric is calculated by
$$\frac{1}{2 * \vert \partial \vert * {C}_{NVM}} = {t}_{fe , critical} .$$

16. A method of forming a device comprising:
providing a substrate defined with a device region;
forming a gate stack on the substrate over the device region, the gate stack comprising
a floating gate (FG), the FG includes
a FG dielectric disposed over the substrate, and
a FG electrode disposed over the FG dielectric, and
a control gate (CG), the CG includes
a composite CG dielectric comprising
a first CG dielectric disposed over the FG electrode, and
a second CG dielectric disposed over the first CG dielectric, the second CG dielectric comprises a negative capacitance second CG dielectric, and
a CG electrode disposed over the second CG dielectric;
forming a first source/drain (S/D) region disposed adjacent to the first sidewall of the gate stack and a second S/D region disposed adjacent to the second gate sidewall of the second gate.

17. The method of claim 16 wherein the negative capacitance second CG dielectric comprises a ferroelectric second CG dielectric, wherein the ferroelectric second CG dielectric comprises barium-titanium oxide (BaTiO₃), hafnium-zirconium oxide (HfZrO₂) or doped hafnium oxide (HfO₂).

18. The method of claim 16 wherein
the first dielectric CG layer produces a parasitic capacitance Cₜₒₚ;
the ferroelectric second CG dielectric layer produces a negative parasitic capacitance C_{fe};
the FG dielectric produces a parasitic capacitance C_{bottom};
the first S/D produces a parasitic capacitance C_{drain};
the second S/D produces a parasitic capacitance C_{source}; and
wherein the Cₜₒₚ, the C_{source}, the C_{drain} and the C_{bottom} together form a parasitic capacitance C_{NVM}.

19. The method of claim 18 wherein an absolute value of the C_{fe} of the second CG dielectric is about 4× larger than C_{NVM}.

20. The method of claim 19 wherein the second CG dielectric has a thickness less than a critical thickness of the second CG dielectric, wherein the critical thickness of the second CG dielectric is calculated by
$$\frac{1}{2 * \vert \partial \vert * {C}_{NVM}} = {t}_{fe , critical} .$$
